(19) United States
(12) Patent Application Publication
(10) Pub. No.: US 2013/0135831 A1
(43) Pub. Date: May 30, 2013

(54) TOUCH MODULE

(71) Applicants: YU-JU HSU, Zhubei (TW); PO-SHENG SHIH, Zhubei (TW)

(72) Inventors: YU-JU HSU, Zhubei (TW); PO-SHENG SHIH, Zhubei (TW)

(73) Assignee: SHIH HUA TECHNOLOGY LTD., Zhubei City (TW)

(21) Appl. No.: 13/445,849

(22) Filed: Apr. 12, 2012

(30) Foreign Application Priority Data
Nov. 28, 2011 (TW) 100143629

(51) Int. Cl. H05K 5/00; H05K 1/00; B82Y 30/00; B82Y 99/00

(52) U.S. Cl. 361/752; 361/751; 361/757; 977/742; 977/932

(57) ABSTRACT

A touch module includes a touch element, a shell body and a decoration film. The shell body defines a curved touch area. The curved touch area is figured to touch the touch element. The touch element covers the curved touch area. The decoration film is an outer layer of the touch module. The shell body, the touch element and the decoration film are incorporated into an integrated structure.

### RELATED APPLICATIONS

This application claims all benefits accruing under 35 U.S.C. §119 from Taiwan Patent Application No. 100143629, filed on Nov. 28, 2011 in the Taiwan Intellectual Property Office, the disclosure of which is incorporated herein by reference.

### BACKGROUND

1. Technical Field

The present disclosure relates to a touch module.

2. Discussion of Related Art

Various Electronic devices with touch functions have been developed. Appearances of the electronic devices tend to be curved to have a 2.5 dimensional structure or a 3 dimension structure. However, processes to make the curved appearances of the electronic devices are always limited by the traditional materials.

In view of materials, materials of transparent conductive layers in traditional touch panels are indium tin oxides (ITO). However, ITO is a rigid material, and cannot be bend. Therefore, in a process of making the curved appearance, the material of ITO is easily damaged, thereby the electrical conductivity of the transparent conductive layer made of ITO is decreased.

Traditional methods for making the curved appearances include the following two steps of: adhering the ITO layers to curved glass substrates; and then adhering to cover lens of electronic devices by adhering a hard material to another hard material processes. Because the yield of the method is low, the electronic devices with both curved appearances and touch functions are not easy to produce, the product costs are expensive.

What is needed, therefore, is to provide a touch module, which can overcome the above shortages.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic view of one embodiment of a touch module, including a touch element and a decoration film.

FIG. 2 is a cross-sectional view of the touch module along a broken line II-II shown in FIG. 1.

FIG. 3 is a schematic view of the touch element and the decoration film shown in FIG. 1.

FIG. 4 is one embodiment of making a touch module.

FIGS. 5-8 show a flow chart view of one embodiment of making a touch module.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

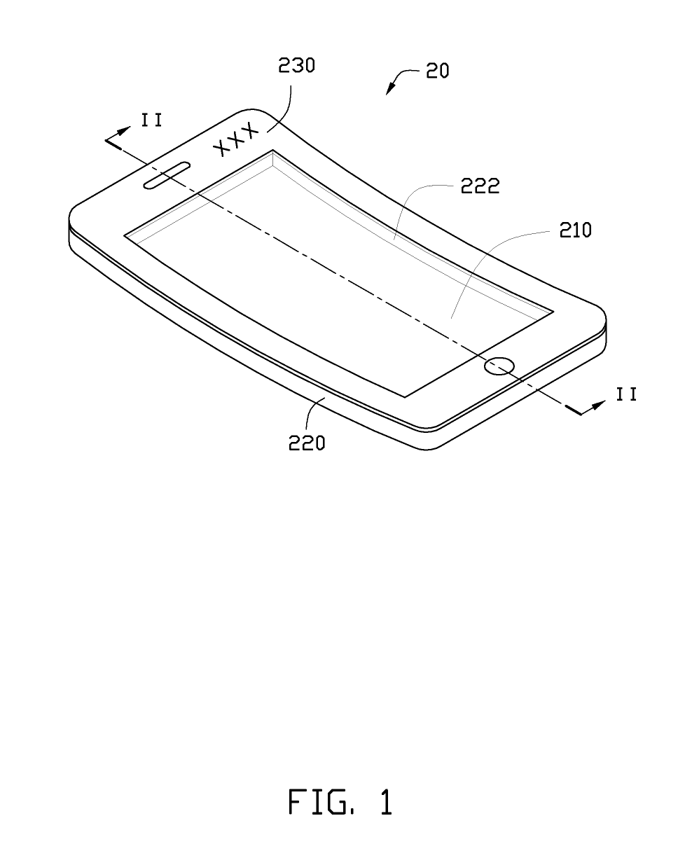

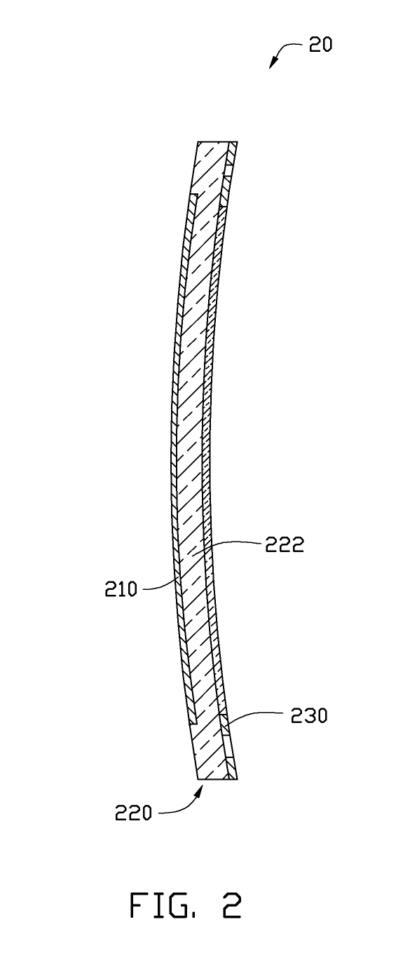

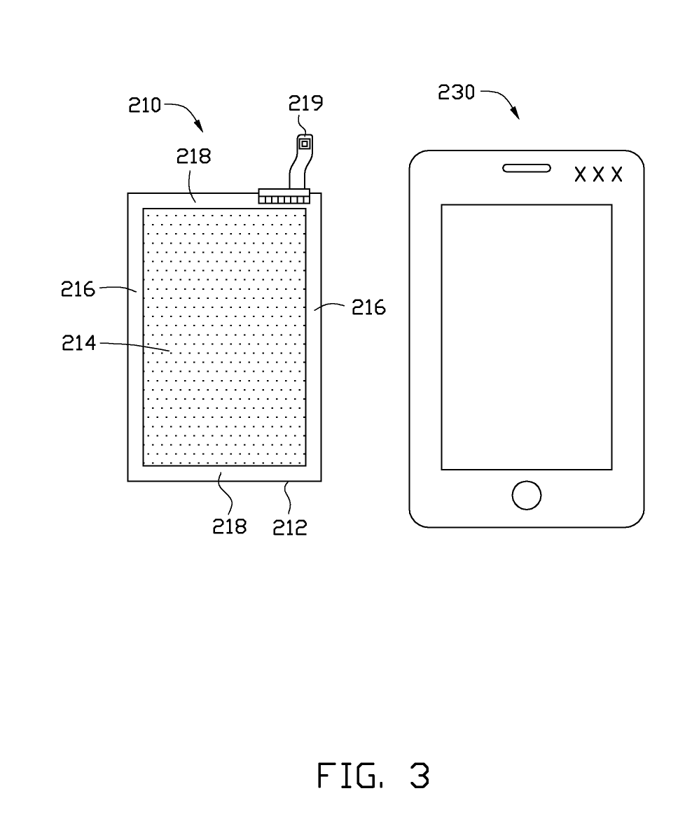

Referring to FIGS. 1, 2 and 3, one embodiment of a touch module 20 having a curved appearance is provided. The touch module 20 includes a touch element 210, a shell body 220, and a decoration film 230. The shell body 220 has a curved appearance. The shell body 220 defines a curved touch area 222. The touch area 222 can show a display page of an electronic device using the touch module 20. The touch area 222 can be used to be touched to produce a signal, especially an electrical signal. The touch element 210 covers the curved touch area 222, and is configured to sense the signal produced by touching the touch area 222. The touch element 210, the shell body 220, and the decoration film 230 are an integrated structure.

The touch module 10 is stereoscopic, and has a 2.5-dimension (2.5-D) or 3-dimension (3-D) structure. The touch module 10 can be used as a cover lens of a mobile phone, a shell of a vehicle navigation system, a shell of a Japanese portrait 3-D printing touch panel, and other electronic device shells.

The shell body 220 is a non-flat structure, and can be in an arc shape, or a stepped shape. Therefore, the shell body 220 has a curved appearance. The touch area 222 is defined at a curved part of the shell body 220, thus the touch area 222 also has a curved shape. The shell body 220 includes an outer surface and an inner surface opposite to the outer surface. The outer surface is what is shown to a user. An outer surface of the touch area 222 is a part of the outer surface of the shell body 220, and an inner surface of the touch area 222 is a part of the inner surface of the shell body 220. The touch element 210 and the decoration film 230 are attached to the two opposite surfaces of the shell body 220. In one embodiment, the touch element 210 is located on the inner surface of the shell body 220, and the decoration film 230 is located on the outer surface of the shell body 220. Thus, the shell body 220 is fixed between the touch element 210 and the decoration film 230. In another embodiment, the touch element 210 is located between the shell body 220 and the decoration film 230.

The shell body 220 can be used as a shell of a mobile phone, a navigation device shell, a steering wheel curst, or other electronic device shell. The shell body 220 can be made by an injection molding method. A material of the shell body 220 can be a transparent material or a non-transparent material. The transparent material can be polystyrene (PS), polycarbonate (PC), or poly(methyl mechacrylate) (PMMA). The non-transparent material can be acrylonitrile-butadiene-styrene copolymer (ABS), poly(ethylene terephthalate) (PET), polycarbonate/acrylonitrile-butadiene-styrene blend (PC/ABS), polycarbonate/poly(butylene terephthalate) blend (PC/PBT), polycarbonate/poly(ethylene terephthalate) blend (PC/PET), polycarbonate/poly(methyl mechacrylate) (PC/PMMA), or polyamide (PA). If the material of the shell 220 is transparent, the touch module 20 can be used in a display device. If the material of the shell 220 is non-transparent, the touch module 20 can be used in/on a steering wheel and other non display devices.

Peripheries of the touch element 210 are covered by the shell body 220, thus the touch element 210 is fixed on the shell body 220. The touch area 222 is curved, and the touch element 210 is a flexible element. Therefore, a shape of the touch element 210 changes with the shape of the touch area 222. The touch element 210 is fixed at edges of the touch area 222, and displays in the same curved shape with the touch area 222 in the touch module 20. In one embodiment, the touch area 222 of the shell body 220 is arc-shaped, the touch element 210 covers the touch area 222 according to the arc-shaped change trend of the touch area 222, and fixed at the peripheries of the touch area 222. Thus, the touch element 210 is also arc-shaped in the touch module 20. When the touch area 222 is stepped shaped, the touch element 210 is fixed on the peripheries of the touch area 222 as the shape of the touch area 222, such that the touch element 210 is also stepped shaped in the touch module 20.

In one embodiment, the shell body 220 is made of poly(methyl mechacrylate) (PMMA) and used as a mobile cell front cover. The shell body 220 includes an arc-shaped touch area 222 located in the middle of the shell body 220. The arc-shaped touch area 222 is defined by two parallel arc lines and two parallel straight lines.

The touch element 210 can be a capacitance type carbon nanotube touch sensor. The touch element 210 can include a carbon nanotube layer 214 and at least two electrodes electrically connected to the carbon nanotube layer 214. The carbon nanotube layer 214 is adjacent to the decoration film 230. The carbon nanotube layer 214 is used as a transparent conductive layer in the touch element 210, therefore the carbon nanotube layer 214 can completely cover the touch area 222 of the shell body 220.

The carbon nanotube layer 214 is transparent, and includes a number of carbon nanotubes. In one embodiment, the carbon nanotubes substantially extend along a same direction, adjacent carbon nanotubes extend along the same direction are joined end to end by Van der Waals force. The carbon nanotube layer 214 includes at least one carbon nanotube film. If the carbon nanotube layer 214 includes a number of carbon nanotube films. The carbon nanotube films can be coplanar without spaces, or overlapped with each other. The carbon nanotubes in the carbon nanotube films are substantially aligned in a preferred and same direction. In one embodiment, the carbon nanotubes in adjacent carbon nanotube films are substantially oriented along a same direction.

A thickness of the carbon nanotube layer 214 is in a range from about 0.5 nanometers to about 100 micrometers. In one embodiment, the thickness of the carbon nanotube layer 214 ranges from about 100 nanometers to about 200 nanometers. The carbon nanotube film is flexible, and can be folded into any shapes without being broken. The carbon nanotube film is also good in transparency and electrical conductivity. The carbon nanotube layer 214 can be transparent. A transparency of a single carbon nanotube film can be greater than 85%.

The at least two electrodes are located on the carbon nanotube layer 214. Materials of the electrodes can be metal, carbon nanotubes, conductive silver pastes or other conductive materials. If the electrodes are made of carbon nanotubes or conductive silver pastes, the electrodes are flexible, and the electrical conductivity of the electrodes can have little or no affect on being bended.

The touch element 210 can further include a flexible substrate 212. The carbon nanotube layer 214 is located on the flexible substrate 212. The carbon nanotube layer 214 is located between the substrate 212 and the decoration film 230. The flexible substrate 212 is to support the carbon nanotube layer 214 and the at least two electrodes. The flexible substrate 212 is made of an electrically insulated material, such as, PC, (PMMA, PET, poly(ether sulphone) (PES), cellulose ester, polyvinyl chloride (PVC), benzo-cyclo-butene (BCB), or acrylic resin. In one embodiment, the substrate 212 is made of PET.

The touch element 210 can also further include a flexible printed circuit board 219. The flexible printed circuit board 219 is located on one side of the carbon nanotube layer 214 and electrically connected to the at least two electrodes. The flexible printed circuit board 219 can also be electrically connected to other units, which can make the touch element 210 work.

In one embodiment, the touch element 210 includes a PET substrate 212, the carbon nanotube layer 214, two first electrodes 216, two second electrodes 218, and the flexible printed circuit board 219. A single carbon nanotube film used as the carbon nanotube layer 214 is attached to the PET substrate 212. The two first electrodes 216 are separately located on the PET substrate 212. The two second electrodes 218 are separately located on the PET substrate 212. The two first electrodes 216 are electrically insulated from the two second electrodes 218. The flexible printed circuit board 219 is electrically connected to the two first and second electrodes 216, 218 and the carbon nanotube layer 214. The two first electrodes 216 and the two second electrodes 218 are made by printing conductive silver paste on four edges of the carbon nanotube layer 214. The two first electrodes 216 and the two second electrodes 218 are flexible and can be curved as the shape change of the inner surface of the shell body 220.

The carbon nanotube layer 214 is made of a single carbon nanotube film. The single carbon nanotube film is a free-standing structure such that the carbon nanotube layer 214 is also a free-standing structure. Wherein, “a free-standing structure” includes, but is not limited to, when the carbon nanotube film is placed on a frame or two separate supporters, part of the carbon nanotube film which is not in contact with the frame or two separate supporting elements would be suspended between parts of the frame or between two supporters and yet will maintain film structure integrity. The carbon nanotube layer 214 includes a number of carbon nanotubes substantially parallel to each other and preferred aligned along a same extending direction. Most of carbon nanotubes in the carbon nanotube layer 214 are joined end-to-end at the same extending direction. Furthermore, the carbon nanotube layer 214 includes a number of carbon nanotube bundles. The carbon nanotube bundles are preferred aligned along the same direction and joined end-to-end to form the carbon nanotube layer 214. Lengths of the carbon nanotube bundles are substantially equal.

The carbon nanotubes have a good electrically conductivity along axial directions thereof. Axes of the carbon nanotubes in the carbon nanotube layer 214 substantially extend along a same direction, thus, a resistance of the carbon nanotube layer 214 at the carbon nanotubes axial extending direction is less than other directions. Therefore, the carbon nanotube axial extending direction is defined to a low resistant direction. In one embodiment, the two first electrodes 216 are arranged along substantially perpendicular to the low resistant direction. A resistance of the carbon nanotube layer 214 at a direction substantially perpendicular to the low resistance direction is greater than any other directions, therefore, the direction substantially perpendicular to the low resistance direction is defined to a high resistance direction. In the carbon nanotube layer 214, a few carbon nanotubes are randomly arranged. The randomly arranged carbon nanotubes contact with adjacent carbon nanotubes. Thus, the carbon nanotube layer 214 along the high resistance direction is electrically conductive. The resistance of the carbon nanotube layer 214 at the high resistance direction is greater than at other directions. An electrical conductivity of the carbon nanotube layer 214 at the high resistance direction is lower than an electrical conductivity of the carbon nanotube layer 214 at the other resistance directions. The two second electrodes 218 are arranged by substantially being perpendicular to the high resistance direction.

It can be understood that the touch element 210 can also be added other function layers, such as a shielding layer or a protecting layer.

The decoration film 230 is an outer surface of the touch module 20. Therefore, when the touch module 20 is used, the decoration film 230 faces a user. The decoration film 230 is used to mark the touch module 20, which makes the touch module 20 having special shapes or colors. Thus, the touch module 20 can have a beautiful appearance, and also can display touched push buttons and trade mark. The decoration film 230 is located on an outer surface of the shell body 220. A shape of the decoration film 230 is coupled with that of the outer surface of the shell body 220. The outer surface of the shell body 220 is an outer surface of the touch module 20, which can be seen by a user. The decoration film 230 can protect the shell body 220 from damage, such as scraping. The decoration film 230 can further include a metal film layer. Therefore, the decoration film 230 shows a metallic luster. The metal film layer is formed by a vacuum evaporation method, a vacuum sputtering method, or other method. The touch module 20 can also show the metallic luster. When the touch module 20 is used in a display device, the decoration film 230 corresponding to the touch area 222 is transparent. The decoration film 230 can be designed to various color at non-touch area of the shell body 220.

In one embodiment, the decoration film 230 is located on the outer surface of the shell body 220. A part of the decoration film 230, which corresponds to the touch area 222, is transparent. The other part of the decoration film 230 can be mainly in black with a trademark of a mobile cell printed thereon.

The touch element 210, the shell body 220, and the decoration film 230 are integrated into the touch module 20. The touch element 210, the shell body 220 and the decoration film 230 are one-step making. Thus, the touch element 210 and the decoration film 230 are tightly fixed on the shell body 220. The touch element 210 is flexible. The shell body 220 can be a 2.5-D structure or a 3-D structure. Therefore the touch module 20 can have touch function, and be a stereoscopic structure.

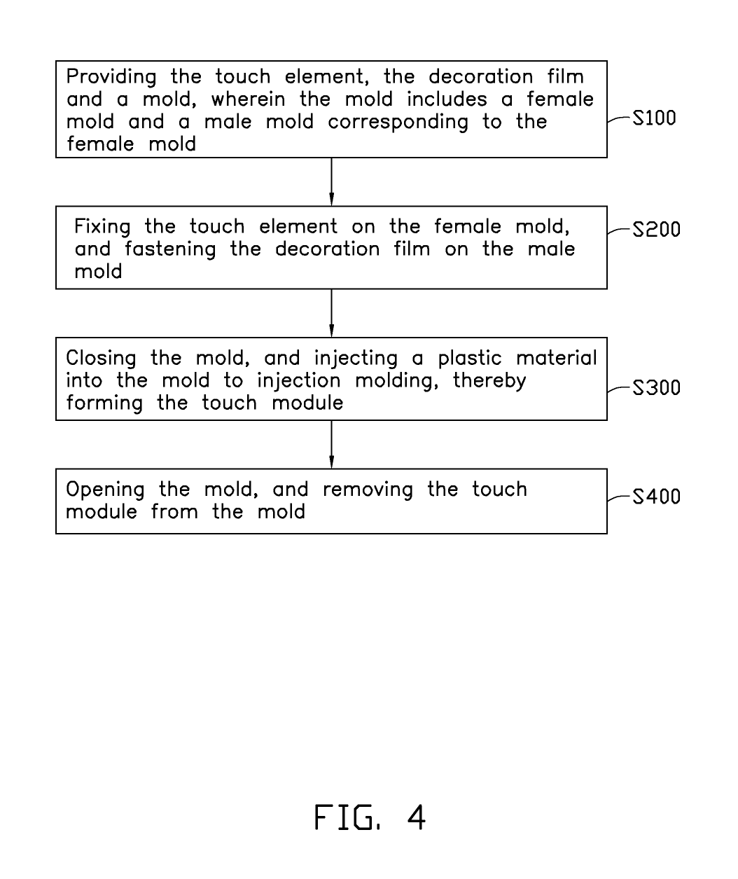

Referring to FIG. 4, one embodiment of a method for making the touch module 20 is provided. In the method, an in-mold decoration process and a double surface filming process are combined to prepare the touch module 20. The method includes the following steps.

S100, providing the touch element 210, the decoration film 230 and a mold 100, wherein the mold 100 includes a female mold 110 and a male mold 120 corresponding to the female mold 110;

S200, fixing the touch element 210 on the female mold 110, and fastening the decoration film 230 on the male mold 120;

S300, closing the mold 100, and injecting a plastic material into the mold 100 to injection molding, thereby forming the touch module 20; and

S400, opening the mold 100, and removing the touch module 20 from the mold 100.

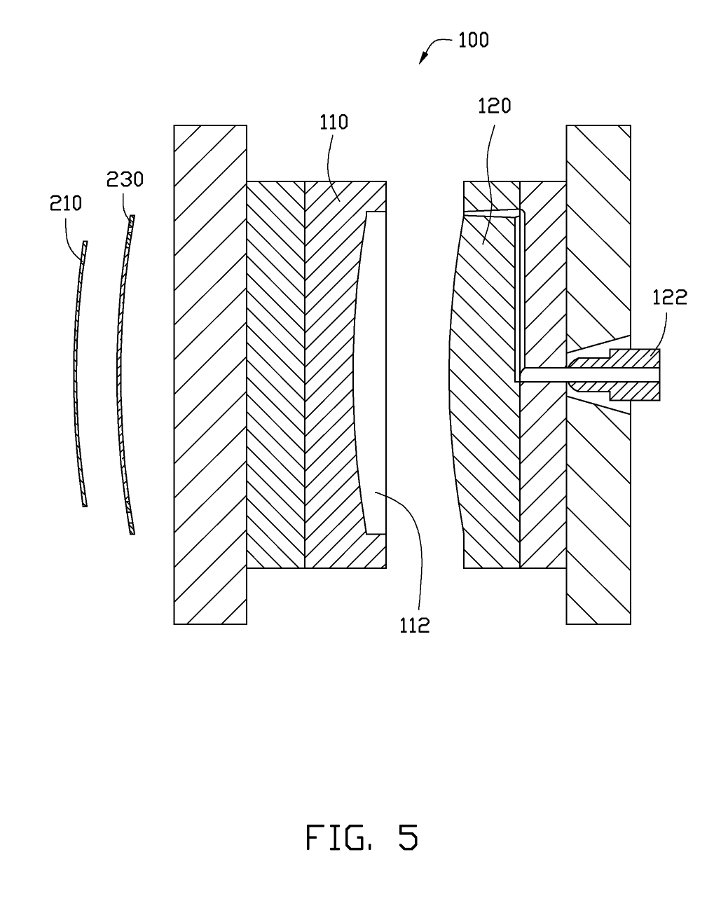

In step S100, referring to FIG. 5, the female mold 110 can couple with the male mold 120 to define a mold cavity 112. A shape of the mold cavity 112 corresponds to the shape of the touch module 20, therefore the shape and the structure of the mold cavity 112 is selected by those of the touch module 20. The mold cavity 112 can both receive the touch element 210 and the decoration film 230 in the mold cavity 112. The mold cavity 112 can be designed according to the shape and structure of the touch module 20. The female mold 110 can define a first curved shape, and the male mold 120 can define a second curved shape. In the mold cavity 112, the first curved shape couples with the second curved shape to form a third curved shape corresponding to the shape of the touch module 20. Therefore, a curved-shaped touch module 20 is formed in the following steps.

The female mold 110 has a first parting surface facing to the male mold 120. The first parting surface of the female mold 110 defines a selected region to fix the touch element 210. A shape of the first parting surface of the female mold 110 is corresponding to a shape of the touch element 210, therefore the touch element 210 can be fixed on the first parting surface of the female mold 110.

An injection through hole 122 is defined by the male mold 120. The plastic material can be injected into the mold cavity 112 through the injection through hole 122. In one embodiment, the injection through hole 122 is located near the edge of the mold cavity 112. The injection through hole 122 corresponds to the non-touch area of the shell body 220. Thus, a material head is made by the plastic material deposited at the injection through hole 122. And the material head is formed at the non-touch area of the shell body 220. Therefore, the electrical conductivity of the carbon nanotube layer 214 in the touch element 210 is substantially not affected by the material head. It can be understood that the number of the injection through holes 122 is not limited. The male mold 120 has a second parting surface facing to the female mold 110. The second parting surface defines a specific region. A shape of the specific region of the second parting surface is coupled with the shape of the decoration film 230 such that the decoration film 230 can be fixed on the second parting surface of the male mold 120.

The mold 100 can further include a first transferring film device (not shown). The first transferring film device includes a pair of transferring film wheels and a pair of guide wheels. The transferring film wheels respectively located two opposite side of the mold 100. The transferring film wheels can bring the decoration film 230 into the mold cavity 112. The guide wheels can direct a transferring direction of the decoration film 230.

The mold 100 can also further include a second transferring film device (not shown). The structure of the second transferring film device is the same as that of the first transferring film device. The second transferring film device can bring the touch element 210 into the mold cavity 112 of the mold 100.

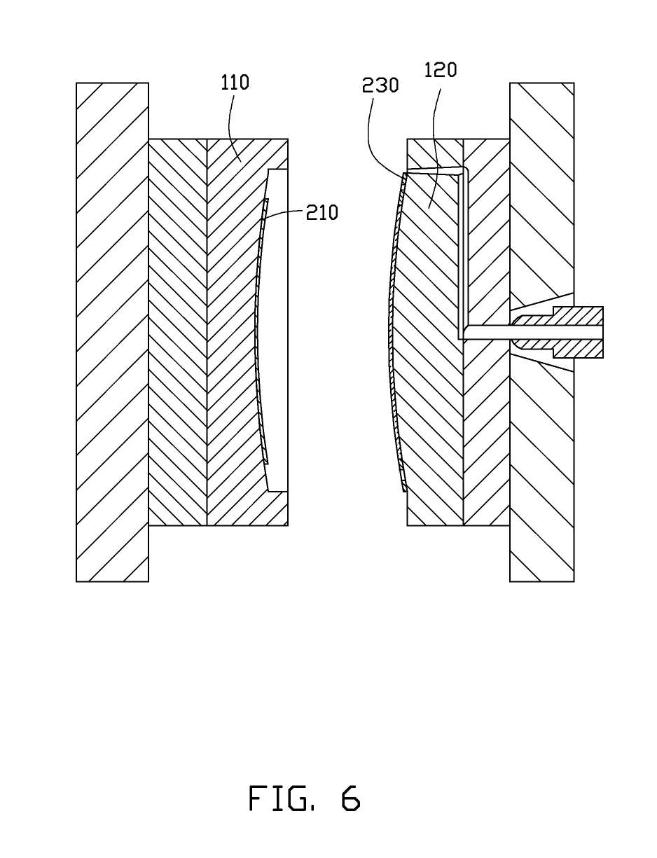

Referring to FIG. 6, in step S200, the touch element 210 is fastened on the selected region of the first parting surface of the female mold 110 to make the touch element 210 have the first curved shape, and the decoration film 230 is fixed on the specific region of the second parting surface of the male mold 120 to make the decoration film 230 have the second curved shape. In one embodiment, the touch element 210 can be fixed on the female mold 110 by a vacuum absorption method.

In one embodiment, the step S200 further includes: transferring the decoration film 230 by the first transferring film device, and the decoration film 230 being brought between the female mold 110 and the male mold 120 along the second parting surface of the male mold 120; fixing the decoration film 230 on the specific region of the second parting surface, and the decoration film 230 being attached to the second parting surface of the male mold 120; transferring the touch element 210 by the second transferring film device, and the touch element 210 being brought between the female mold 110 and the male mold 120 along the first parting surface of the female mold 110; and fastening the touch element 210 on the selected region of the first parting surface, and the flexible substrate 212 of the touch element 210 being attached to the first parting surface of the female mold 110.

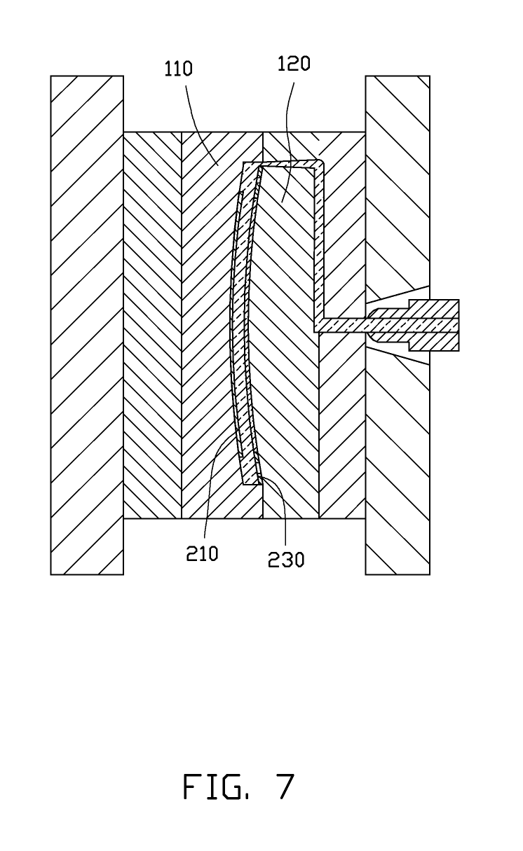

Referring to FIG. 7, the step S300 can further include the following steps of combining the female mold 110 with the male mold 120 to define the mold cavity 112; injecting the plastic material into the mold cavity 112 through the injection through hole 122 until the mold cavity 112 is full with the plastic material; adhering the touch element 210 and the decoration film 230 to surfaces of the plastic material in the mold cavity 112; cooling down the plastic material in the mold cavity 112, thereby the plastic material in the mold cavity 112 forms the shell body 220, while simultaneously the touch element 210 and the decoration film 230 are attached to the shell body 220. Therefore, the touch module 20 is formed. Wherein, the plastic material is a raw material of the shell body 220. The material head is formed at the edges of the shell body 220. In one embodiment, the plastic material is PET.

During the process of closing the mold 100, the decoration film 230 attached to the plastic material and the touch element 210 attached to the plastic material are respectively cut down from the first transferring film device and the second transferring film device. The decoration film 230 attached to the plastic material is separated from the decoration film fixed on the first transferring film device, and the touch element 210, attached to the plastic material, is separated from the touch element fastened to the second transferring film device.

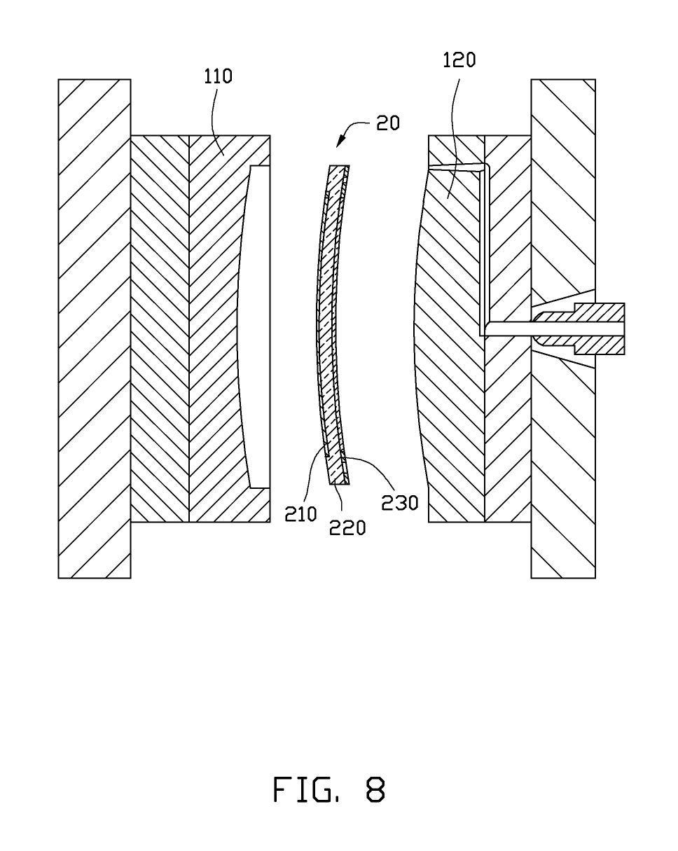

Referring to FIG. 8, the step S400 includes the steps: separating the female mold 110 from the male mold 120; and ejecting the touch module 20, thereby the touch module 20 attaching to the decoration film 230 and the touch element 210 is obtained.

The touch element 210 includes the carbon nanotube layer 214, the carbon nanotube layer 214 has flexural endurance, high pressure resistance, high temperature resistance, properties stability and surface abrasion resistance. During the above-mentioned in-mold decoration process of making the touch module 20, the carbon nanotube layer 214 substantially has no damage, the carbon nanotube layer 214 still has good electrical conductivity. For example, after undergoing 285 centigrade degrees and 700 atms, the carbon nanotube layer 214 is still flexible and not broken, electrical conductivity of the carbon nanotube layer 214 is substantially unchanged, and resistance of the carbon nanotube layer is substantially unchanged. The electrodes are electrically connected to the carbon nanotube layer 214 are made of electrically conductive silver paste. After the in-mold decoration process of making the touch module 20, and the electrodes substantially have no damage. And the conductivities of the electrodes are substantially unchanged. The flexible printed circuit board 219 substantially has no damage, after the above-mentioned in-mold decoration process. Therefore, the touch element 210 can retain its properties, after the in-mold decoration process. Thus, the touch module 20 made by the above-mentioned method has touch function, electronic devices using the touch module 20 can also have touch function. In addition, because the carbon nanotube layer 214 and the electrodes in the touch element 210 are flexible, the touch element 210 is flexible. The touch element 210 can be provided to the mold 100 by a roll-to-roll process. Thus, the touch module 20 can be quickly produced, and cost of making the touch module 20 can be reduced.

The touch module 20 is made by combining the in-mold decoration process with the double surface filming process. The touch element 210 and the decoration film 230 are fixed on the shell body 220. Simultaneously, the shell body 220 is formed. Therefore, the touch element 210 attached to the shell body 220, the decoration film 230 attached to the shell body 220, and the shell body 220 formed, are one-step making. Therefore the method for making the touch module 20 is easy. Because the touch element 210 and the decoration film 230 are flexible and the shell body 220 can be curved, the touch module 20 can be curved. The touch module 20 can have a 3-D structure or a 2.5-D structure. In addition, the yield of making the touch module 20 having curved appearance can be improved.

It is to be understood that the above-described embodiment is intended to illustrate rather than limit the disclosure. Variations may be made to the embodiment without departing from the spirit of the disclosure as claimed. The above-described embodiments are intended to illustrate the scope of the disclosure and not restricted to the scope of the disclosure.

It is also to be understood that the above description and the claims drawn to a method may include some indication in reference to certain steps. However, the indication used is only to be viewed for identification purposes and not as a suggestion as to an order for the steps.

What is claimed is:

1. A touch module, comprising:
a shell body defining a curved touch area, the curved touch area capable of producing a signal;
a touch element covering the curved touch area, and the touch element being configured to sense the signal and
a decoration film being an outer layer of the touch module,
wherein the shell body, the touch element and the decoration film are incorporated in an integrated structure.

2. The touch module of claim 1, wherein the touch element and the decoration film are attached to two opposite surfaces of the shell body.

3. The touch module of claim 1, wherein the touch element is located between the decoration film and the shell body.

4. The touch module of claim 1, wherein the touch element is a capacitance type touch element.

5. The touch module of claim 1, wherein the touch element comprises a carbon nanotube layer covering the curved touch area and at least two electrodes electrically connected to the carbon nanotube layer.

6. The touch module of claim 5, wherein the carbon nanotube layer comprises a plurality of carbon nanotubes substantially oriented along a same direction.

7. The touch module of claim 5, wherein the touch element further comprises a flexible substrate away from the decoration film, and the carbon nanotube layer is located on the flexible substrate.

8. The touch module of claim 7, wherein the touch element further comprises a flexible printed circuit board that is electrically connected to the at least two electrodes.

9. The touch module of claim 1, wherein edges of the touch element are embedded into the shell body.

10. The touch module of claim 9, wherein the touch element is fixed near peripheries of the curved touch area of the shell body.

11. The touch module of claim 1, wherein the curved touch area is arc-shaped or stepped-shaped.

12. The touch module of claim 11, wherein the touch element is arc-shaped or stepped-shaped.

13. The touch module of claim 1, wherein the shell body is a mobile cell shell, a navigation device shell, or a guiding wheel shell.

14. The touch module of claim 1, wherein the shell body is transparent, the decoration film corresponding to the curved touch area is transparent.

15. The touch module of claim 1, wherein the shell body comprises a material that is selected from the group consisting of polystyrene, polycarbonate, poly(methyl mechacrylate) acrylonitrile-butadiene-styrene copolymer, poly(ethylene terephthalate), polycarbonate/acrylonitrile-butadiene-styrene blend, polycarbonate/poly(butylene terephthalate) blend, polycarbonate/poly(ethylene terephthalate) blend, polycarbonate/poly(methyl mechacrylate), and polyamide.
